(19) United States
(12) Patent Application Publication
(10) Pub. No.: US 2009/0294817 A1
(43) Pub. Date: Dec. 3, 2009

(54) FERROELECTRIC MEMORY DEVICE

(75) Inventor: Takehisa Ishida, Tokyo (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: Sony Corporation, Tokyo (JP)

(21) Appl. No.: 12/472,437

(22) Filed: May 27, 2009

(30) Foreign Application Priority Data
May 29, 2008 (SG) 200804443-0

(51) Int. Cl. H01L 29/51; H01L 21/30

(52) U.S. Cl. 257/295; 438/3; 257/E29.164; 257/E21.211

(57) ABSTRACT

A ferroelectric memory device comprising a dielectric layer comprising a mixture and/or a compound that comprises a ferroelectric organic polymer and an oxidiser and/or deioniser, and a pair of electrodes configured to apply an electric field to the dielectric layer. Also a method of fabricating a memory device.

### FIELD OF THE INVENTION

The present invention relates to a ferroelectric memory device and a method of fabricating a memory device.

### BACKGROUND

Ferroelectric polymer is a promising material for some electronic devices. For example, it is suitable for a use in memory device fabrication, such as non-volatile memory.

A ferroelectric thin film can be formed from a solution using spin-coating, die-coating, screen-printing or other coating processes. This reduces the production cost of ferroelectric polymer devices compared to inorganic based materials.

However, ferroelectric polymer devices may suffer from a decrease of switchable polarisation or remanence after repetition of polarisation reversal. This phenomenon may be called fatigue. Remanence is an important property for a ferroelectric memory, because the magnitude of the output signal is proportional to remanence. Organic materials may have a higher fatigue rate than inorganic materials.

### SUMMARY OF THE INVENTION

In general terms, one aspect of the invention proposes a memory device with a ferroelectric organic polymer and an oxidiser and/or deioniser. This may have the advantage of reducing fatigue. The oxidiser and/or deioniser may be 4-vinylpyridine and the ferroelectric organic polymer may be Polyvinylidenefluoride (PVDF), copolymer of Polyvinylidenefluoride and Trifluoroethylene (P(VDF/TrFE)), Polyaminodifluoroborane (PADFB), Polyundecanoamide (Nylon11) or a mixture of any combination thereof.

In a first specific expression of the invention there is provided a ferroelectric memory device according to claim 1.

In a second specific expression of the invention there is provided a method of fabricating a memory device according to claim 10.

### BRIEF DESCRIPTION OF THE DRAWINGS

One or more example embodiments of the invention will now be described, with reference to the following figures, in which:

FIG. 1 is a memory device according to an exemplary embodiment,

FIG. 2 is a typical fatigue trend of P(VDF/TrFE),

FIG. 3 is a hysteresis curve of P(VDF/TrFE) before and after fatigue,

FIG. 4(a) is a result of TOF-SIMS analysis before fatigue,

FIG. 4(b) is a result of TOF-SIMS analysis after fatigue,

FIG. 5 is a comparison of fatigue trend using P(VDF/TrFE), P(VDF/TrFE)+4VP and P(VDF/TrFE)+4VP+PVA layer, and

FIG. 6 is a flow diagram of a method of fabrication according to the exemplary embodiment.

### DETAILED DESCRIPTION

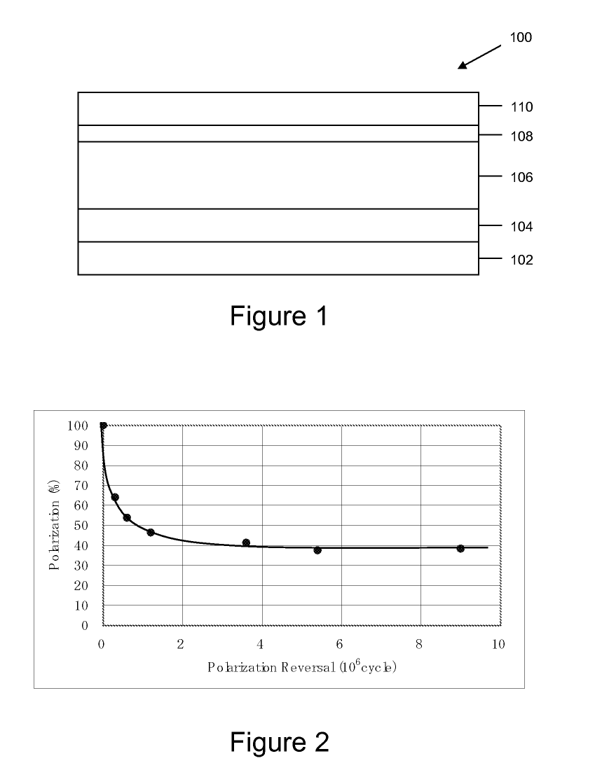

FIG. 1 shows a memory device 100 according to an exemplary embodiment. The device 100 is a multilayer structure with a glass substrate 102, an ITO electrode 104, a dielectric layer 106 and a metal electrode 110. The electrodes 104,110 are used to apply an electric field to the dielectric layer 106 to store or read a “1” or “0” state for each memory cell.

FIG. 2 shows a fatigue trend when the dielectric layer 106 is a ferroelectric organic polymer P(VDF/TrFE). Switchable polarisation decreases by 30% after 10⁵ times of polarisation reversal and decreases by 60% after 4×10⁶ cycles of polarisation reversal. This phenomenon degrades reliability or durability of the memory device.

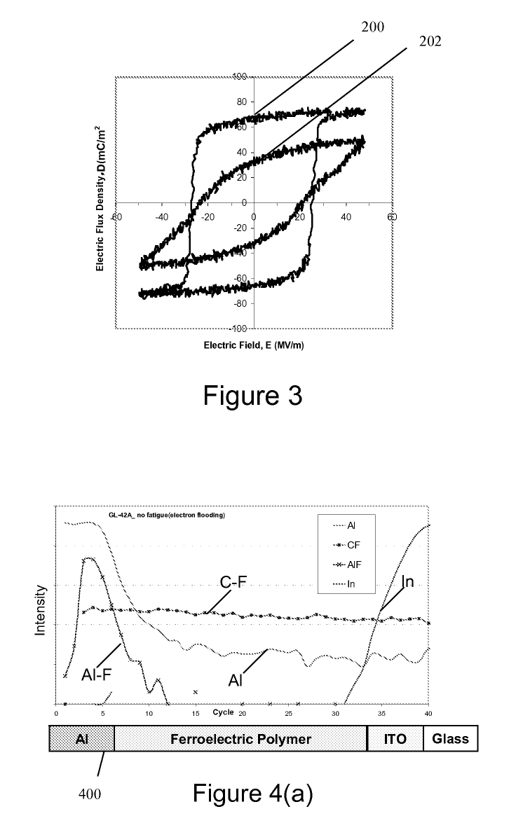

FIG. 3 shows hysteresis curves before and after fatigue, respectively. The remnant flux density (Pᵣ) 200 after 10⁷ cycles of polarisation reversal is decreased from the Pᵣ before fatigue 202 (eg: 65 mC/m² to 30 mC/m²).

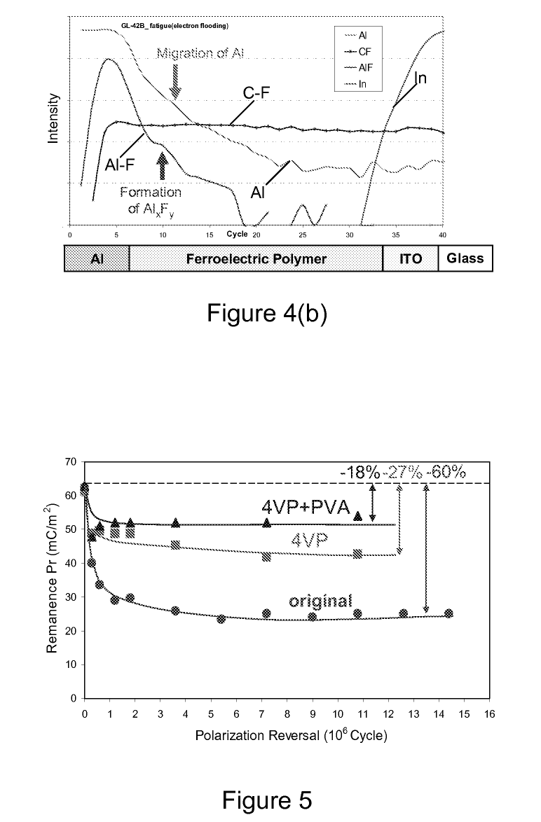

FIG. 4(a) shows the chemical cross section of an unused Glass/ITO/P(VDF/TrFE)/Al device obtained by TOF-SIMS (Time-of-flight Secondary Ion Mass Spectrometry) analysis. An alternating electric field was applied between the ITO and Al electrodes for 10⁷ cycles to reverse polarization repeatedly. FIG. 4(b) shows the chemical cross section after fatigue. Al ions may be migrating into the ferroelectric polymer layer and AlₓF_{y} may be produced around the interface 400 between an Al electrode and a P(VDF/TrFE) layer. Therefore, fatigue may be being caused by the reactions shown in Equations (1) and (2).

—(H₂C—CF₂)ₙ—+e⁻→—(H₂C—CF)ₙ—+F⁻ (1)

3F⁻+Al³⁺→AlF₃ (2)

Due to the alternating electric field, electrons are injected into the P(VDF/TrFE) layer and may ionise the Fluorine to generate free F⁻ ions. The free F⁻ ions may react with the migrated A³⁺ ion at the interface between the P(VDF/TrFE) layer and the Al electrode. Thus, AlF₃ may be produced and may affect the ferroelectric properties.

To prevent the above-mentioned problem, we introduced 4-vinylpyridine (4VP) monomer into the ferroelectric polymer as an oxidiser and/or deioniser. The 4VP may be mixed as a monomer with the ferroelectric organic polymer or may be a branch of a ferroelectric organic polymer backbone.

The 4VP may react with free fluorine ions in the ferroelectric polymer. The 4VP may reduce the likelihood that free fluorine ions will react with aluminium ions.

FIG. 5 shows fatigue deterioration of P(VDF/TrFE) compared to a mixture of P(VDF/TrFE) with 10 wt % 4VP. The P(VDF/TrFE) 4VP mixture resulted in a 27% deterioration in Pᵣ after 10⁷ cycles of polarisation reversal compared to a 60% deterioration with P(VDF/TrFE) film without 4VP.

A protection layer 108 such as Polyvinylalcohol (PVA) coated between the aluminium electrode 110 and dielectric layer 106 may further prevent fatigue caused by repeated polarisation reversal. In FIG. 5 a 50 nm thick PVA layer between the aluminium electrode and the ferroelectric polymer layer, resulted in only a 18% deterioration in Pᵣ after 10⁷ cycles of polarisation reversal. The PVA layer may block migration of metal ions into the ferroelectric polymer layer and further reduce the chance of metal ions and free fluorine ions reacting.

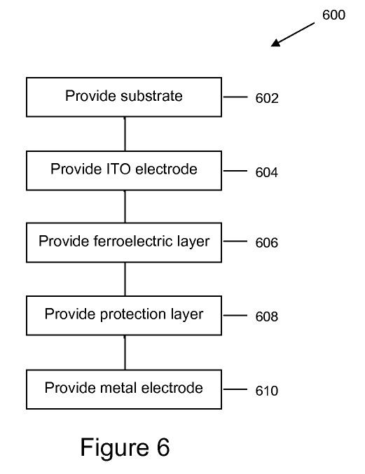

FIG. 6 shows a method 600 of fabricating a memory device. At 602 a glass substrate is provided. At 604 an ITO electrode is provided on the glass substrate. At 606 a dielectric layer is provided on the ITO electrode. At 608 a protection layer is provided on the dielectric layer. At 610 a metal electrode such as aluminium is provided on the protection layer.

Providing the dielectric layer 606 may be implemented by mixing P(VDF/TrFE) and 4VP with a solvent to form a dielectric solution. The dielectric solution is then coated or printed onto the ITO electrode. Alternatively PVDF and 4VP can be copolymerised to form a dielectric solution. For example Ozone-preactivated PVDF can be copolymerised with 4VP in an N-methyl-2-pyrrolidone (NMP) solution. By this process, graft copolymer 4VP-g-PVDF which has PVDF backbones and 4VP side chains is obtained. Alternatively the PVDF may be preactivated by an electron beam.

Providing the protection layer 608 may be implemented by spin coating, die coating or any printing method such as screen printing or gravure printing the PVA layer onto the dielectric layer.

The device 100 may then be connected, encapsulated and annealed.

Whilst exemplary embodiments of the invention have been described in detail, many variations are possible within the scope of the invention as will be clear to a skilled reader. For example the substrate may also be Si or plastic film. The bottom electrode may also be Al, Au, Cu, or Ni. If the both bottom and top electrodes are metal, a further protection layer may be used between the bottom electrode and ferroelectric layer to further reduce fatigue.

1. A ferroelectric memory device comprising
a dielectric layer comprising a mixture and/or a compound that comprises a ferroelectric organic polymer and an oxidiser and/or deioniser, and
a pair of electrodes configured to apply an electric field to the dielectric layer.

2. The device in claim 1 wherein the dielectric layer comprises a mixture of a ferroelectric organic polymer and a deionising and/or oxidising monomer.

3. The device in claim 2 wherein the deionising and/or oxidising monomer is 4-vinylpyrigine (4VP) monomer.

4. The device in claim 1 wherein the dielectric layer comprises a compound comprising a ferroelectric organic polymer backbone and a deionising and/or oxidising branch.

5. The device in claim 4 wherein the dielectric layer comprises a graft copolymer of PVDF and 4-vinylpyridine (4VP-g-PVDF).

6. The device in any one of claims 1 to 5 wherein the ferroelectric organic polymer comprises at least one of
Polyvinylidenefluoride (PVDF),
copolymer of Polyvinylidenefluoride and Trifluoroethylene (P(VDF/TrFE)),
Polyaminodifluoroborane (PADFB), and
Polyundecanoamide (Nylon11).

7. The device in any one of the preceding claims wherein at least one electrode is a metal.

8. The device in claim 7 further comprising a protection layer between the at least one metal electrode and the dielectric layer.

9. The device in claim 8, wherein the protection layer is Polyvinylalcohol (PVA).

10. A method of fabricating a memory device comprising
providing a dielectric solution comprising a ferroelectric organic polymer and an oxidiser and/or deioniser.

11. The method of claim 10 further comprising
providing a first electrode;
forming a dielectric layer from the dielectric solution; and
providing a second electrode on the dielectric layer.

12. The method in claim 11 further comprising providing a protection layer between the dielectric layer and at least one electrode.

13. The method in any one of claims 10 to 12 wherein providing the dielectric solution comprises mixing a ferroelectric organic polymer, a deionising and/or oxidising monomer and a solvent.

14. The method in any one of claims 10 to 12 wherein providing the dielectric solution comprises grafting the ferroelectric organic polymer to an oxidising and/or deionising monomer.
